(19) United States
(12) Patent Application Publication
(10) Pub. No.: US 2006/0030076 A1
(43) Pub. Date: Feb. 9, 2006

(54) Semiconductor device

(75) Inventors: Hiroshi Kobayashi, Kawasaki (JP); Naoki Ishikawa, Kawasaki (JP); Kenji Kobae, Kawasaki (JP); Hidehiko Kira, Kawasaki (JP); Norio Kainuma, Kawasaki (JP); Shuichi Takeuchi, Kawasaki (JP); Takayoshi Matsumura, Kawasaki (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: FUJITSU LIMITED, Kawasaki (JP)

(21) Appl. No.: 11/246,267

(22) Filed: Oct. 11, 2005

Related U.S. Application Data
(62) Division of application No. 10/785,969, filed on Feb. 26, 2004.

(30) Foreign Application Priority Data
Jun. 13, 2003 (JP) 2003-169607

(51) Int. Cl. H01L 21/48; H01L 21/44; H01L 21/50

(52) U.S. Cl. 438/108; 438/106; 438/613

(57) ABSTRACT

The semiconductor device of the present invention is capable of restricting alloying metals and improving electrical connection between a semiconductor chip and a mount board. The semiconductor device comprises: the semiconductor chip having terminal sections; and bumps for electrical connection, the bumps being formed at the terminal sections. Each of the bumps is made of a two-layer wire, which includes a core member and a jacket member, and formed by a stud bump bonding process.

### CROSS REFERENCE TO RELATED APPLICATION

This application is a division of Ser. No. 10/785,969, filed Feb. 26, 2004, which is based on Japanese Application No. 2003-169607 filed Jun. 13, 2003.

### BACKGROUND OF THE INVENTION

The present invention relates to a semiconductor device.

Conventionally, when a bare chip (semiconductor chip) is mounted on a mount board by a flip-chip mounting process, projected electrodes called bumps are formed at terminal sections of the semiconductor chip. The semiconductor chip is electrically connected to electrodes of the mount board with the bumps. The bumps are ordinarily made of solder or gold.

These days, semiconductor devices are made smaller, thus number of bumps will be further increased and separations between bumps will be further made narrower. However, in the case that the separations between the bumps are less than several tens μm, if the bumps are made of solder, which is an ordinary material of bumps, the solder is melted by heat for connecting the bumps, so that the melted solder sometimes shorts the adjacent electrodes. Therefore, it is difficult to use solder as bumps.

To solve the problem of solder bumps, bumps are formed by a stud bump bonding process with gold wires, and a semiconductor chip is flip-chip-mounted on a mount board by vibration energy of ultrasonic waves (see Japanese Patent Gazette No. 2001-060602).

However, the gold bumps have following disadvantages.

Gold, which is ordinarily used as a material of stud bumps, forms an alloy, e.g., AuAl, Au₅Al₂, with aluminum after the connection by ultrasonic waves. With progressing the alloying for a long time, volume of bumps vary, so that voids called Kirkendall voids are formed between gold and an alloy layer, or aluminum and the alloy layer. The voids make electric connection between a semiconductor chip and a mount board unstable, so that resistance must be increased. Terminal sections and bumps are made smaller with reducing separations between the bumps, so that amount of aluminum or gold, which is supplied to the alloy layer, is reduced. Therefore, the voids are easily formed. To restrict alloying, the terminal sections are plated with gold, or an auxiliary material, e.g., silver paste, is applied to connected sections. But, manufacturing cost must be increased.

In FIG. 14, a bare chip 12 is stack-connected on another bare chip (a mount board) 10. The bare chips 10 and 12 respectively have terminal sections 14 and 16. A symbol 18 stands for a gold bump. Gold-aluminum alloy layers 20 are formed between the gold bump 18 and the terminal sections 14 and 16. Kirkendall voids 22 are formed between the alloy layers 20 and gold or aluminum.

### SUMMARY OF THE INVENTION

The present invention was invented to solve the above described disadvantages of the conventional semiconductor devices.

An object of the present invention is to provide a semiconductor device which can restrict alloying metals and improve electrical connection between a semiconductor chip and a mount board.

To achieve the object, the present invention has following structures.

Namely, the semiconductor device of the present invention comprises: a semiconductor chip having terminal sections; and bumps for electrical connection, the bumps being formed at the terminal sections, wherein each of the bumps is made of a two-layer wire, which includes a core member and a jacket member, and formed by a stud bump bonding process.

In the semiconductor device, the core member of the two-layer wire may be made of a material, whose diffusion coefficient of alloying with respect to a material of the terminal sections of the semiconductor chip is small, and the jacket member of the two-layer wire may be made of a metallic material, which is resistant to oxidization.

In the semiconductor device, the core member of the two-layer wire may be made of a material, whose diffusion coefficient of alloying with respect to a material of electrodes of a mount board, to which the bumps are connected, is small, and the jacket member of the two-layer wire may be made of a metallic material, which is resistant to oxidization.

In the semiconductor device, the core member of the two-layer wire may be made of copper or silver, and the jacket member of the two-layer wire may be made of palladium or gold.

In the semiconductor device, the jacket member of the two-layer wire may be formed by plating, and the thickness of the jacket member may be 5000-10000 Å.

A structure of mounting a semiconductor device comprises: the semiconductor device of the present invention; and a mount board on which the semiconductor device is mounted and which is electrically connected to the semiconductor device with the bumps.

Further, in a method of mounting a semiconductor device on a mount board, the bumps of the semiconductor device of the present invention are connected to a mount board by an ultrasonic junction process.

In the present invention, each of the bumps is made of the two-layer wire, which includes the core member and the jacket member, and formed by the stud bump bonding process. Especially, if the core member of the two-layer wire is made of the material, e.g., copper, silver, whose diffusion coefficient of alloying with respect to the material of the terminal sections of the semiconductor chip, e.g., aluminum, gold, is small, forming voids (Kirkendall voids) can be prevented, so that electric connection between the semiconductor chip and the mount board can be stable for a long time.

Further, in the case that the jacket member, which covers the core member, is made of the metallic material, which is resistant to oxidization, even if the core member is made of a material, e.g., copper, which cannot well form into a ball shape, the jacket member helps the core member form into a good ball shape. Therefore, the bumps can be formed by the ordinary stud bump bonding process.

### BRIEF DESCRIPTION OF THE DRAWINGS

Embodiments of the present invention will now be described by way of examples and with reference to the accompanying drawings, in which:

FIG. 1 is an explanation of an ultrasonic bonding machine for a stud bump bonding process;

FIG. 2 is an explanation view of forming a ball;

FIG. 3 is an explanation view of a bump;

FIG. 4 is an explanation view of a semiconductor device;

FIG. 5 is a sectional view of a two-layer wire, in which a ball is formed;

FIG. 6 is an explanation view a horn of the ultrasonic bonding machine, which sucks and holds the semiconductor device;

FIG. 7 is an explanation view of a mount board, on which resin for under filling is applied;

FIG. 8 is an explanation view of the semiconductor device, which is connected to the mount board by an ultrasonic junction process;

FIG. 9 is an explanation view of the semiconductor device, which has been connected on the mount board;

FIG. 10 is an explanation view of the semiconductor device, which has been mounted on the mount board;

FIG. 11 is an explanation view of the semiconductor device, whose terminal sections are electrically connected to terminal sections of the mount board with wires;

FIG. 12 is an explanation view of the semiconductor device, which is molded with resin;

FIG. 13 is a graph of increasing rate of resistance of bumps made of gold wires and bumps made of two-layer wires; and

FIG. 14 is an explanation view of the gold bump, in which Kirkendall voids are formed.

### DETAILED DESCRIPTION OF THE EMBODIMENTS

Preferred embodiments of the present invention will now be described in detail with reference to the accompanying drawings.

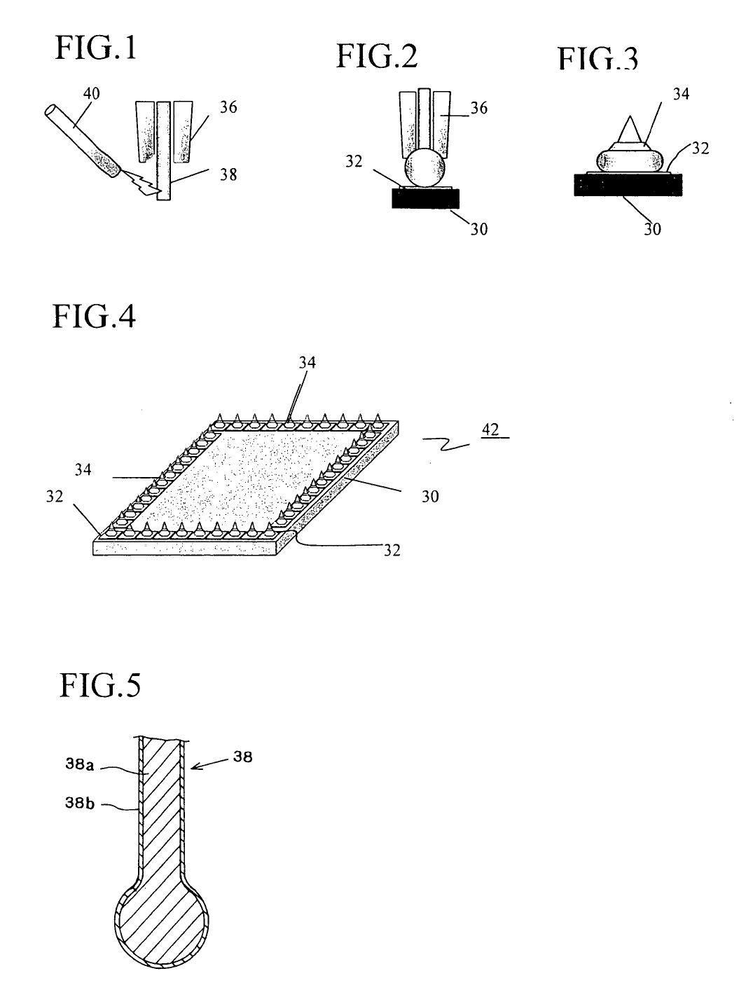

FIGS. 1-3 show the steps of forming a bump 34 on a terminal section 32 of a bare chip 30 by a stud bump bonding process.

In FIG. 1, a two-layer wire 38 is pulled out from a capillary 36 of a known ultrasonic bonding machine. A front end of the two-layer wire 38 is heated by a spark between a torch 40 and the front end of the two-layer wire 38, so that a ball is formed at the front end of the two-layer wire 38.

In FIG. 2, a ball-shaped part of the two-layer wire 38 is pressed onto the terminal section 32 of the bare chip 30 by the known stud bump bonding process, which is performed by the ultrasonic bonding machine. Then, the ball-shaped part is torn off from the two-layer wire 38, so that a projected bump 34 can be formed (see FIG. 3).

A semiconductor device 42 having the bumps 34 is shown in FIG. 4. The bumps 34 are respectively formed on the terminal sections 32.

FIG. 5 is a sectional view of the two-layer wire 38, in which the ball is formed.

The two-layer wire 38 has a core member 38a and a jacket member 38b, which covers the core member 38a. In the present embodiment, the core member 38a is made of a material (e.g., copper, silver), whose diffusion coefficient of alloying with respect to a material (e.g., aluminum) of the terminal sections 32 of the semiconductor chip 30 is small; the jacket member 38b is made of a metallic material (e.g., palladium, gold), which is resistant to oxidization. If cost can be ignored, platinum may be used for the jacket member 38b.

In another embodiment, the core member 38a is made of a material (e.g., copper, silver), whose diffusion coefficient of alloying with respect to a material (e.g., aluminum, gold) of electrodes of a mount board, to which the bumps 34 are connected, is small; the jacket member 38b is made of a metallic material (e.g., palladium, gold), which is resistant to oxidization. If cost can be ignored, platinum may be used for the jacket member 38b.

Preferably, the jacket member 38b is formed on the core member 38a by plating. In the present embodiments, thickness of the jacket member 38b may be 5000-10000 Å.

Alloying speed of metals depends on combinations of metals. For example, in the case of connecting a gold wire to the terminal section of a bare chip, which is made of aluminum, diffusion speed of an aluminum-gold alloy is very fast. Voids (Kirkendall voids) are sometimes formed within 24 hours from initial connection, so stable electrical connection cannot be performed for a long time.

According to an acceleration test, if a copper wire or a silver wire is used instead of the gold wire, diffusion speed of aluminum-copper or silver alloy is 40-50% slower than that of the aluminum-gold alloy. The voids are not observed within a short time from the connection, so stable electrical connection can be performed for a long time. In the case of using the gold wire, the ball-shaped part can be formed at the front end thereof in a first step of forming the bump. However, in the case of using a copper wire or a silver wire, the ball-shaped part cannot be well formed at a front end of the wire by spark. Especially, a large facility is required to treat copper wires. Further, copper is easily oxidized in the air, so that films of copper oxide are formed in connected sections. The oxide films increase electric resistance and cause open circuit.

On the other hand, in the present embodiment, the two-layer wire 38 is used. The core member 38a is made of, for example, a copper wire or a silver wire, whose diffusion coefficient of alloying with respect to a material of the terminal sections or the connected sections (e.g., aluminum, gold) is small, or whose diffusion speed of alloying with respect to the material of the terminal sections is slow. With this structure, forming voids (Kirkendall voids) can be substantially prevented, so that the bumps 34, which can maintain good electric connectivity for a long time, can be made.

Further, the core member 38a is covered with the jacket member 38b made of a metallic material, which is resistant to oxidization. Therefore, even if the core member 38a is made of copper which cannot be well formed into the ball shape solely, the ball can be well formed at the front end of the two-layer wire 38. Therefore, the bumps 34 can be formed by the ordinary stud bump bonding process with the two-layer wire 38. Note that, thickness of the jacket member 38b may be very thin, so manufacturing cost can be restricted.

As described above, the ball cannot be well formed at the front end of the sole copper wire or the sole silver wire. The inventor thinks that an oxide film is formed on a surface of the wire, and it prevents spark for forming the ball.

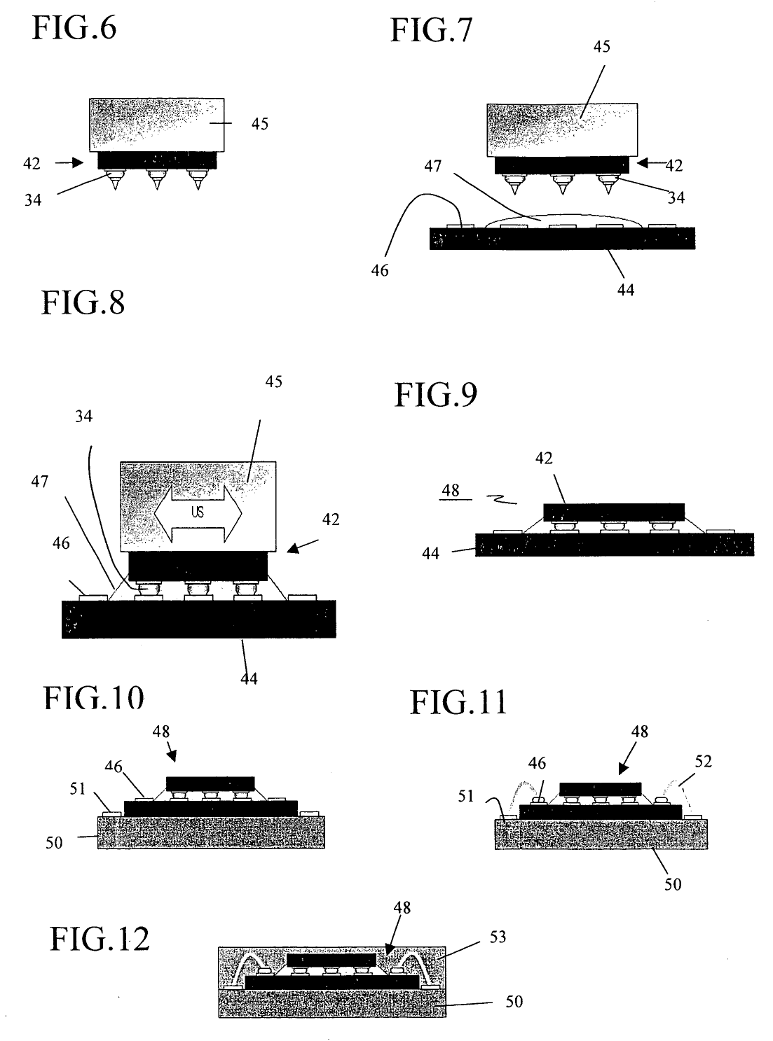

Steps of mounting a semiconductor device 42, which has the bumps 34 formed by the process described above, onto a mount board (a bare chip) 44 will be explained with respect to FIGS. 6-9.

Firstly, the bumps 34 of the semiconductor device 42 are headed downward, and the semiconductor device 42 is sucked and held by a horn 45 of an ultrasonic bonding machine (see FIG. 6).

The semiconductor device 42 is moved to a prescribed position above the mount board 44. Resin 47 for under filling has been previously applied on an upper face of the mount board 44 except terminal sections 46 (see FIG. 7).

Ultrasonic waves are applied to a connecting part between the semiconductor device 42 and the mount board 44 so as to electrically connect the bumps 34 to the mount board 44. By connecting the semiconductor device 42 to the mount board 44, a semiconductor device 48, which is stack-connected to the mount board 44, can be produced (see FIG. 9). Note that, the resin 47 may be applied to a gap between the semiconductor device 42 and the mount board 44 after the stack connection.

Steps of mounting the semiconductor device 48 onto a substrate 50 and molding the same with resin will be explained with reference to FIGS. 10-12.

Firstly, the semiconductor device 48 is mounted onto the substrate 50 (see FIG. 10). Then, the terminal sections 46 of the mount board 44 and terminal sections 51 of the substrate 50 are electrically connected by wires 52 (see FIG. 11). Finally, the semiconductor device 48 is molded with resin 53 (See FIG. 12).

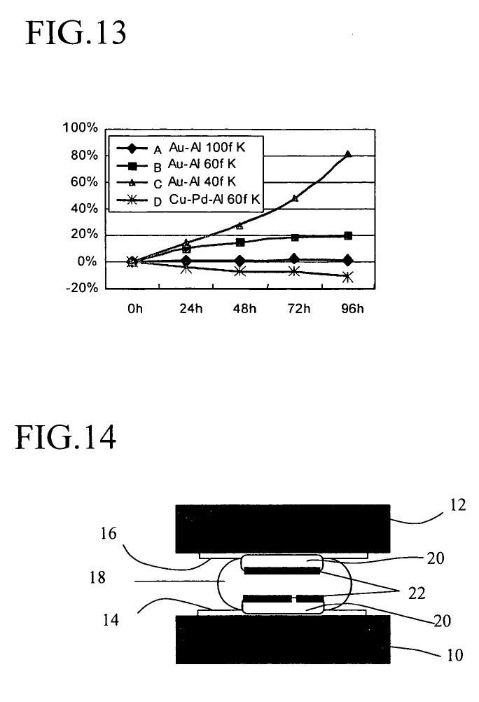

FIG. 13 shows a graph of increasing rate of resistance of bumps made of gold wires (A-C) and bumps made of the copper-palladium two-layer wires (D). The bumps of all samples A-D were ultrasonic-connected to terminals (aluminum electrodes) of mount boards. Then, acceleration tests (aging) of the samples A-D were executed at temperature of 200° C.

Note that, in the sample A, the gold bumps are formed with separations of 100 μm; in the sample B, the gold bumps are formed with separations of 60 μm; in the sample C, the gold bumps are formed with separations of 40 μm; in the sample D, the bumps made from the two-layer wire are formed with separations of 60 μm.

In the case of forming the gold bumps with narrow separations or pitches (the samples B and C), the rate of increasing resistance was great. The inventor thinks that Kirkendall voids were formed by aging, so that the resistances was increased. On the other hand, in the case of forming the gold bumps with pitches of 100 μm (the sample A), the rate of increasing resistance was not so great.

In the case of the bumps relating to the present invention (the sample D), the resistance was reduced by aging. The reason is that energy of ultrasonic waves was not fully applied to the bumps and the mount board when the ultrasonic connection was begun, so the both were not completely connected each other, then the both were completely connected with aging. In the sample D, no Kirkendall voids were formed.

The invention may be embodied in other specific forms without departing from the spirit or essential characteristics thereof. The present embodiments are therefore to be considered in all respects as illustrative and not restrictive, the scope of the invention being indicated by the appended claims rather than by he foregoing description and all changes which come within the meaning and range of equivalency of the claims are therefore intended to be embraced therein.

What is claimed is:

1. A method of mounting a semiconductor device on a mount board,
wherein said semiconductor device includes a semiconductor chip having terminal sections and bumps for electrical connection, which are formed at the terminal sections, each of the bumps is made of a two-layer wire, which includes a core member and a jacket member and which is formed by a stud bump bonding process, and
the bumps are connected to said mount board by an ultrasonic junction process.

2. A method of mounting a semiconductor device on a mount board, according to claim 1,
wherein the core member of said two-layer wire is made of a material, whose diffusion coefficient of alloying with respect to a material of the terminal sections of said semiconductor chip is small, and
the jacket member of said two-layer wire is made of a metallic material, which is resistant to oxidization.

3. A method of mounting a semiconductor device on a mount board, according to claim 1,
wherein the core member of said two-layer wire is made of a material, whose diffusion coefficient of alloying with respect to a material of electrodes of a mount board, to which said bumps are connected, is small, and
the jacket member of said two-layer wire is made of a metallic material, which is resistant to oxidization.

4. A method of mounting a semiconductor device on a mount board, according to claim 1,
wherein the core member of said two-layer wire is made of copper or silver, and
the jacket member of said two-layer wire is made of palladium or gold.

5. A method of mounting a semiconductor device on a mount board, according to claim 1,
wherein the jacket member of said two-layer wire is formed by plating, and
the thickness of the jacket member is 5000-10000 Å.
